(19) United States
(12) Patent Application Publication
(10) Pub. No.: US 2005/0087883 A1
(43) Pub. Date: Apr. 28, 2005

(54) Flip chip package using no-flow underfill and method of fabrication

(75) Inventors: Tan Kim Hwee, Singapore (SG); Roman Perez, Singapore (SG); Antonio Dimaano, Singapore (SG); Lau Kee Kwang, Singapore (SG); Alex Chew, Singapore (SG)

Correspondence Address: STEPHEN B. ACKERMAN, 28 DAVIS AVENUE, POUGHKEEPSIE, NY, 12603, US

(73) Assignee: Advanpack Solutions Pte. Ltd.

(21) Appl. No.: 10/690,996

(22) Filed: Oct. 22, 2003

(51) Int. Cl. H01L 23/48

(52) U.S. Cl. 257/778

(57) ABSTRACT

A design and method of fabrication for a semiconductor package is described. A solder bumped semiconductor chip is assembled to a metallized package substrate utilizing the solder bumps. The interconnecting solder bumps are properly constrained at assembly by the introduction of a no-flow underfill between the chip and the substrate. The no-flow underfill constrains the solder of the solder bumps so as to maintain the desired size and shape.

### FIELD OF THE INVENTION

The present invention relates in general to the design and fabrication methods of semiconductor flip chip packages utilizing solder bumped interconnections.

### BACKGROUND OF THE INVENTION

The following three U.S. Patents relate in general to the design and methods of fabrication of semiconductor packages utilizing solder ball interconnections.

U.S. Pat. No. 6,441,487B2 dated Aug. 27, 2002, issued to P. Elenius et al., describes a chip scale flip chip package utilizing large ductile solder balls.

U.S. Pat. No. 6,429,530B1 dated Aug. 6, 2002, issued to W. T. Y. Chen describes a miniaturized chip scale ball grid array package using a solder bumped chip carrier.

U.S. Pat. No. 6,344,234B1 dated Feb. 5, 2002, issued to H. M. Dalal et al. describes a method for forming reflowed solder balls utilizing a metal cap of low temperature wetting material over the solder balls.

The advent of VLSI technology in the semiconductor field has resulted in the demand for high density packaging. Semiconductor packaging traditionally has three levels of package. The first level, a single chip module is made up of a semiconductor chip attached to a substrate that includes interconnections to the next level of package. The substrate and chip assembly is usually molded in an encapsulant for environmental protection. The second level of package, usually a printed circuit card mounts and interconnects the single chip modules and has a connector system to the third level package, usually a planar printed circuit board.

The utilization of VLSI semiconductor chips in commercial electronic products such as cameras, camcorders, DVD players, etc., has demanded that semiconductor packages be highly reliable and space efficient in their designs. In addition military applications require lightweight, space efficient, highly reliable packaging structures.

Elimination of a level of package has been a driving force in electronic system design in the recent past. This reduction in packaging level would allow for closer spacing of semiconductor chips thereby reducing signal delay times. In addition the reduction of a level of package would increase product reliability and decrease product costs. One design currently in use is direct chip attach. In this design chips are flip chip mounted onto a substrate, usually ceramic, and the assembly sealed in an enclosure for environmental protection. The environmental protection is required to protect the semiconductor and the interconnections against corrosive elements and mechanical disturbances. The inclusion of enclosures for environmental protection results in larger packages with longer distances between semiconductor chips and thereby longer signal delays.

In addition, advances in VLSI technology in the semiconductor field has created the need for higher interconnection density on the surface of the semiconductor chip. These interconnections are used to connect the chip terminals to the next level of package or printed circuit board. The need for higher density interconnections results from the smaller circuit devices fabricated by the recent manufacturing advances. The smaller circuits in turn result in higher circuit counts per chip. The higher circuit count requires more signal input, and signal output connections; in addition the higher circuit count requires more power to be delivered to the chip requiring more power connections. This need for higher interconnection density has resulted in interconnection techniques such as solder bumps that are capable of utilizing the total area of the chip thus providing more interconnections per chip.

Solder bump or solder ball technology for the interconnection of semiconductor chips to the next level of package have been developed and in use over a period of years. The advent of portable devices in the electronics industry has introduced the need for smaller, lighter, and cost effective products. These demands have resulted in the development of fabrication methods that are less complex as well as designs that eliminate a level of package; i.e., chip scale packaging.

The use of solder bumped semiconductor chips requires that the design of the package and methods of fabrication is capable of providing appropriate interconnect contacts. These interconnect contacts need to have a wettable surface that mates with the chip solder bumps and also constrains the solder into a spherical shape for proper function. This requirement has resulted in package designs and methods of fabrication that are complicated and costly.

FIG. 1 (Prior Art) depicts a currently used package design where a semiconductor chip 10 with solder bumps 12 is interconnected to a metallized package substrate 14. The metal pattern 16 on the substrate needs to have a means of constraining the solder of the solder bump 12. This constraint is provided by an insulating layer 18 that is fabricated by a many stepped photolithographic method to provide the necessary contacts for the solder bumped chip.

Another method that has been used is the application of a layer of low melting solder on the surface of the solder bumps. When reflowed the low melt solder becomes liquid and metallurgically joins to the substrate pads while the higher melting solder of the solder bump maintains its shape.

### A SUMMARY OF THE INTENTION

Accordingly, it is an object of one or more embodiments of the present intention to provide a design and method of fabrication to simplify the process of providing a semiconductor package with metal contact pads for assembling a solder bumped semiconductor chip.

Another object of one or more embodiments of the present invention is to provide a method of fabrication that will contain the solder of the solder bumps in its desired shape.

It is a further object of one or more embodiments of the present invention that the method of fabrication utilizes presently used processes.

The above objectives are achieved by one or more embodiments of the present invention by the use of a no-flow underfill material between the semiconductor chip and the package. The no-flow underfill supports the chip structure during the assembly operation and controls the flow of the solder.

### BRIEF DESCRIPTION OF THE DRAWINGS

The present invention will be more clearly understood from the following description taken in conjunction with the accompanying drawings in which like reference numerals designate similar or corresponding elements, regions and portions in which:

FIG. 1 is a cross section of the prior art showing a semiconductor chip solder ball interconnected to the package substrate utilizing surface metallurgy with an insulating layer.

FIG. 2 is a cross sectional view of a top surface metallized substrate prior to the introduction of the no-flow underfill.

FIG. 3 is a cross sectional view of a top surface metallized substrate after the introduction of the no-flow underfill.

FIG. 4 is a cross sectional view of a solder bumped semiconductor chip and a metallized substrate with the no-flow underfill.

FIG. 5 is a cross sectional view of the semiconductor chip and the metallized substrate after positioning into an assembly.

FIG. 6 is a cross sectional view of a solder bumped semiconductor chip after reflow of the solder bump.

### DETAILED DESCRIPTION OF THE PREFERRED EMBODIMENT

The demands of electronic products for highly space efficient, cost effective, and reliable components have resulted in the development of semiconductor chip packaging designs and methods of fabrication that are compact and cost efficient. One of these designs eliminates the level of package by directly mounting the semiconductor chip onto a printed circuit card or printed circuit board. The conventional approach of employing a substrate mounted semiconductor chip can be made more space and cost efficient by utilizing materials and fabrication methods that simplify the design and the process.

In packaging semiconductor chips with solder bumps on the front face of the chip, the solder bumps are utilized for interconnections to the next level of package. Generally these interconnections are an array of solder balls that are used for input-output signals and power connections to the semiconductor chip. The solder balls are metallurgically bonded to the next level of package during assembly.

A semiconductor package utilizing solder bump interconnections for interconnecting a semiconductor chip to the package is designed to ensure that the assembly processes provide the properly designed solder ball contact pads both on the semiconductor chip and the package.

On the semiconductor chip the contact pads are formed during wafer processing. Contact pad metallurgy referred to as under bump metallurgy or UBM is deposited over semiconductor chip pads. The contact pads, usually circular, constrain the solder of the solder bumps during the reflow attachment process to the next level of package, so as to provide a functional and reliable electrical interconnection.

The design of the package contact pads and metallurgy has employed many design and fabrication methods for solder containment. On packages with surface metallurgy, in the prior art, a layer of insulating non-wetting material such as epoxy is patterned on the surface of the substrate as shown in FIG. 1. Patterning the insulating layer 18 requires a many step process of applying and curing the epoxy layer. Photolithographic processes are used to open contact holes to the metal layer.

The embodiment of the present invention utilizes a no-flow underfill, epoxy resin based material, to constrain the solder and the solder bump after reflow. This design and method of assembly does not require a non-wetting surface on the substrate or a multi-temperature metallurgy on the semiconductor chip solder bumps.

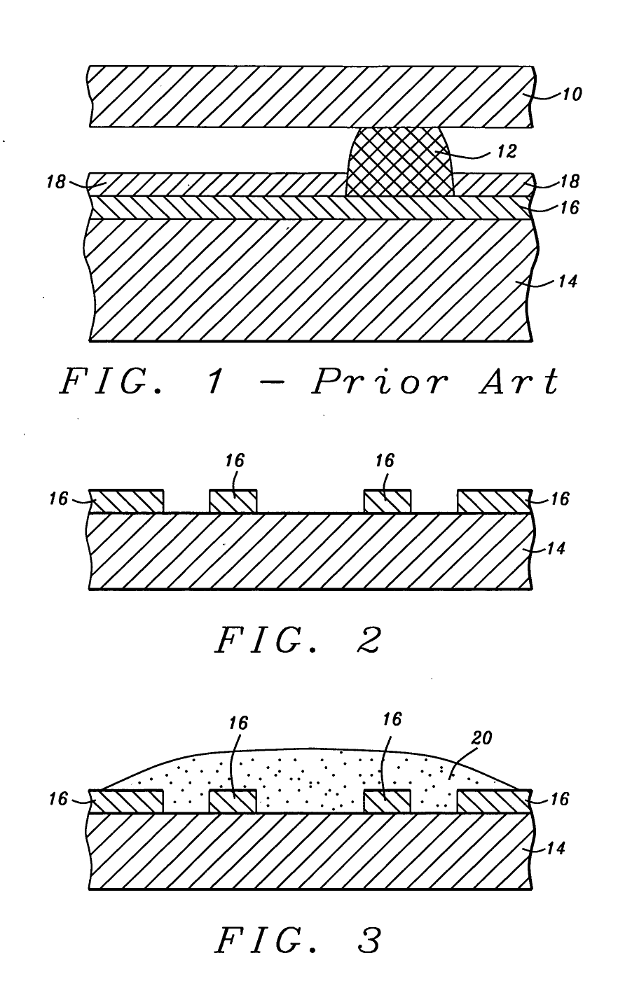

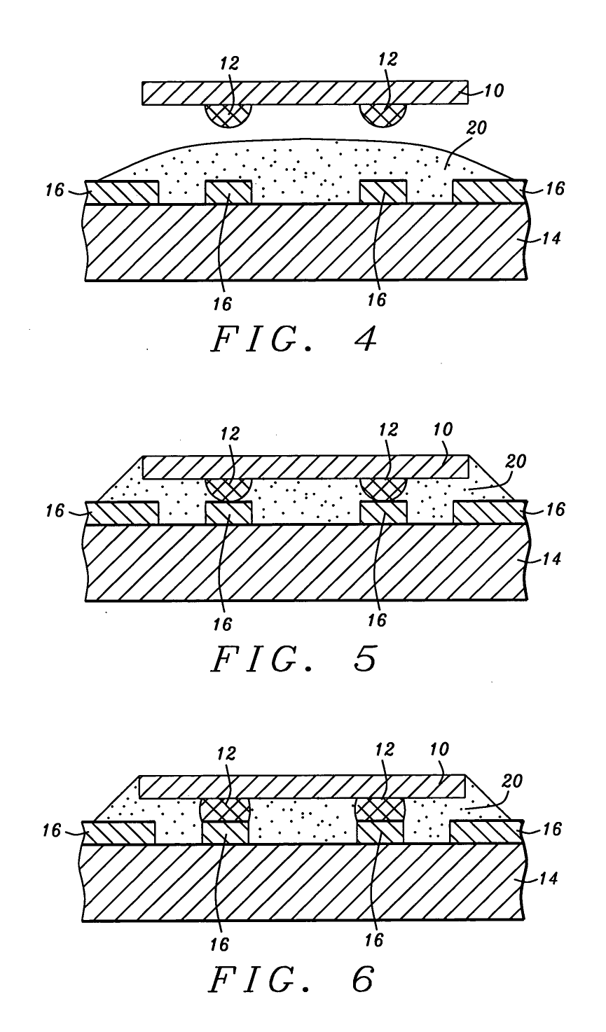

FIG. 2 shows a metallized substrate 14 prior to the no-flow underfill dispensing. The substrate 14 may be any insulating material that is metallizable, such as ceramic, or epoxy based. The metallization 16 may be any electrically conductive material such as copper Cu, nickel Ni, that is patterned by photolithographic means. The patterned metallurgy has a layer of gold Au on the top surface for better wetting. The next step in the process is shown in FIG. 3 where the metallized substrate 14 has the no-flow underfill 20 deposited on it. The solder bumped semiconductor chip 10 is introduced, as shown in FIG. 4, with the metallized substrate 14 and the no-flow underfill 20 prior to positioning of the semiconductor chip 10 on the metallized substrate 14. Positioning of the solder bumped semiconductor chip 10 on the metallized substrate 14 prior to the reflow process is shown in FIG. 5. FIG. 6 shows the final assembly of the solder bumped semiconductor chip 10 and the metallized substrate 14 with the no-flow underfill 20 after curing of the no-flow underfill 20, and reflow of the solder bumps 12. Both processes are performed in an inert atmosphere.

The reflow process has metallurgically bonded the solder bumps 12 to the substrate metallurgy 16. The no-flow underfill 20 has constrained the solder and prevented solder flow along any of the metallized lines of the substrate.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof

1. A semiconductor package comprising:
a solder bumped semiconductor chip;
a surface metallized substrate, connected at said solder bumps to said solder bumped semiconductor chip; and,
a no-flow underfill surrounding connection points of said solder bumped semiconductor chip and said surface metallized substrate.

2. The solder bumped semiconductor chip of claim 1 wherein the solder bumps are composed of lead-tin Pb Sn alloy.

3. The solder bumped semiconductor chip of claim 1 wherein the solder bumps are composed of a single solder alloy.

4. The surface metallized substrate of claim 1 wherein the said substrate has a metallized patterned top surface.

5. The surface metallized substrate of claim 4 wherein the said substrate is ceramic.

6. The surface metallized substrate of claim 4 wherein the said substrate is epoxy.

7. The surface metallized substrate of claim 4 wherein the said substrate is any electrically insulating material that can be metallized.

8. The surface metallized substrate of claim 4 wherein the patterned surface metallurgy is copper Cu.

9. The surface metallized substrate of claim 4 wherein the patterned surface metallurgy is nickel Ni.

10. The surface metallized substrate of claim 4 wherein the patterned surface metallurgy has a gold Au flash on the top surface.

11. The surface metallized substrate of claim 4 wherein the patterned surface is any electrically conductive metal.

12. The surface metallized substrate of claim 4 wherein the patterned surface metallurgy is formed by photolithographic processes.

13. A method of fabricating a semiconductor package, the method comprising the steps of:
providing a semiconductor chip with a plurality of solder bumps on the surface;
providing a substrate with a metallized top surface;
disposing a no-flow underfill to the metallized surface of said surface metallized substrate;
positioning said solder bumped semiconductor chip in contact with said surface metallized substrate to form an assembly;
curing the no-flow underfill; and
reflowing said assembly.

14. The method of claim 13 wherein the curing process is in an inert environment.

15. The method in claim 13 wherein the reflow process is in an inert environment.
